(19) United States
(12) Patent Application Publication
(10) Pub. No.: US 2011/0057558 A1
(43) Pub. Date: Mar. 10, 2011

(54) ORGANIC LIGHT-EMITTING DIODE

(76) Inventors: Isao Takasu, Komae-shi (JP); Yukitami Mizuno, Tokyo (JP); Shintaro Enomoto, Yokohama-shi (JP); Shuichi Uchikoga, Tokyo (JP)

(21) Appl. No.: 12/718,497

(22) Filed: Mar. 5, 2010

Related U.S. Application Data
(63) Continuation of application No. PCT/JP09/65732, filed on Sep. 9, 2009.

(51) Int. Cl. H01L 51/54

(52) U.S. Cl. 313/504

(57) ABSTRACT

An organic light-emitting diode includes an anode and a cathode arranged apart from each other, and an emissive layer arranged between the anode and the cathode and containing a host material and an emitting dopant, the host material containing a plurality of indole skeletons represented by the general formula (1):

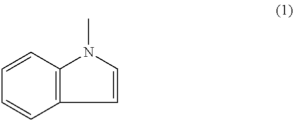

### CROSS-REFERENCE TO RELATED APPLICATION

This is a Continuation Application of PCT Application No. PCT/JP2009/065732, filed Sep. 9, 2009, the entire contents of which are incorporated herein by reference.

### BACKGROUND OF THE INVENTION

1. Field of the Invention

The present invention relates to an organic light-emitting diode.

2. Description of the Related Art

In recent years, organic light-emitting diodes have been attracting attention in view of luminescence technique for next generation displays and illumination. In the early study of organic light-emitting diodes, fluorescence has been mainly used as mechanism of luminescence of an organic layer. However, in recent years, an organic light-emitting diode utilizing phosphorescence which exhibits higher internal quantum efficiency has been attracting attention.

The mainstream emissive layers utilizing phosphorescence in recent years are those in which a host material comprising an organic material is doped with an emissive metal complex including iridium or platinum as a central metal. In the emissive layer having such structure, the larger the overlap between a luminescent spectrum of the host material and an absorption spectrum of an emitting dopant is, the better the energy transfer efficiency from the host material to the emitting dopant is. This is called as Foerster's energy transfer mechanism.

Jpn. J. Appl. Phys. Vol. 39 (2000) pp. L828-L829 and Adv. Mater. 2006, 18, 948-954 disclose an organic light-emitting diode utilizing p-bis-carbazolylphenylene (CBP) or polyvinyl carbazol (PVK) as a host material. For example, when an emissive layer comprising a blue emitting dopant material FIrpic and a polymer host material PVK is deposited, the luminescent wavelength of PVK is 420 nm and the absorption wavelength of FIrpic is 380 nm. Here, in order to transfer energy from a host material to FIrpic more efficiently, a host material with a shorter luminescent wavelength is preferably used.

### BRIEF SUMMARY OF THE INVENTION

According to one aspect of the present invention, there is provided an organic light-emitting diode comprising: an anode and a cathode arranged apart from each other; and an emissive layer arranged between the anode and the cathode and containing a host material and an emitting dopant, the host material containing a plurality of indole skeletons represented by the general formula (1):

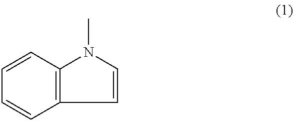

### BRIEF DESCRIPTION OF THE SEVERAL VIEWS OF THE DRAWINGS

FIG. 1 is a cross-sectional view of an organic light-emitting diode of an embodiment of the present invention;

FIG. 2 schematically shows overlap between a luminescent spectrum of a host material and an absorption spectrum of an emitting dopant;

FIG. 3 shows luminescent spectra of polyvinyl indole and polyvinyl(4,6-difluoroindole); and

FIG. 4 shows overlap between luminescent spectra of host materials and an absorption spectrum of an emitting dopant.

### DETAILED DESCRIPTION OF THE INVENTION

The embodiments of the present invention are explained below in reference to the drawings.

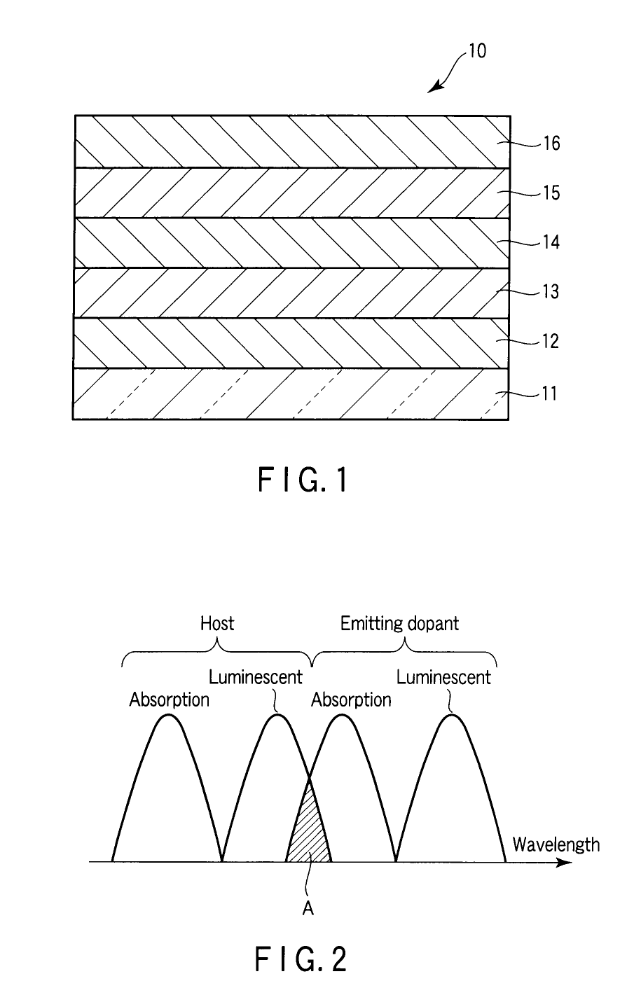

FIG. 1 is a cross-sectional view of the organic light-emitting diode of an embodiment of the present invention.

In the organic light-emitting diode 10, an anode 12, hole injection/transport layer 13, emissive layer 14, electron injection/transport layer 15, and cathode 16 are formed in sequence on a substrate 11. The hole injection/transport layer 13 and electron injection/transport layer 15 are formed if necessary.

Each member of the organic light-emitting diode of the embodiment of the present invention is explained below in detail.

The emissive layer 14 receives holes and electrons from the anode and the cathodes, respectively, followed by recombination of holes and electrons which results in the light emission. The energy generated because of the recombination excites the host material in the emissive layer. An emitting dopant is excited by energy transfer from the excited host material to the emitting dopant, and the emitting dopant emits light when it returns to the ground state.

The emissive layer 14 contains a luminescent metal complex having a central metal such as iridium and platinum (hereinafter, referred to as an emitting dopant), which is doped into the host material consisting of an organic material. As the emitting dopant, any known emissive material can be used. The emitting dopant may be a fluorescent dopant or phosphorescent dopant, but is preferably a phosphorescent dopant having high internal quantum efficiency.

The emitting dopant includes, for example, blue emitting dopant, green emitting dopant, and red emitting dopant. Representative examples of the blue emitting dopant include bis(2-(4,6-difluorophenyl)pyridinato iridium complex (hereinafter, referred to as FIrpic). Representative examples of the green emitting dopant include tris(2-phenylpyridine)iridium complex (hereinafter, referred to as Ir(ppy)₃). Representative examples of the red emitting dopant include bis(2-phenylbenzothiozorato-N,C2′)iridium(acetylacetonato) (hereinafter, referred to as Bt₂Ir(acac)).

As is shown in FIG. 2, as the overlapped area between a luminescent spectrum of a host material and an absorption spectrum of an emitting dopant (indicated by A in FIG. 2) is larger, the efficiency of energy transfer from the host material to the emitting dopant becomes better. A blue emitting dopant has an absorption band in a relatively shorter wavelength range. Thus, in order to obtain efficient luminescence from the blue emitting dopant, a host material having luminescent wavelength in a shorter wavelength region is preferably used. Use of such a host material enables provision of an organic light-emitting diode having improved luminescent efficiency.

In the present embodiment, a host material indicating a shorter luminescent wavelength is used in order to obtain efficient luminescence from a blue emitting dopant. Specifically, a material containing a plurality of indole skeletons represented by the general formula (1) is used.

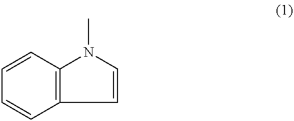

The host material may be those containing a plurality of indole skeletons having one or more methyl groups at 2- or 3-position represented by the general formula (2) below. In the general formula (2), at least one of R2 and R3 is CH₃ and the other is H.

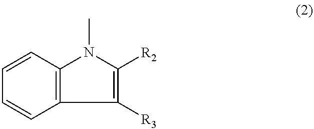

The host material may be those containing a plurality of indole skeletons having one or more fluorine atoms at 4- or 6-position represented by the general formula (3) below. In the general formula (3), at least one of R4 and R6 is F and the other is H.

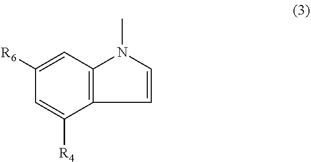

The host material may be those containing a plurality of indole skeletons having one or more methyl groups at 2- or 3-position and one or more fluorine atoms at 4- or 6-position represented by the general formula (4) below. In the general formula (4) at least one of R2 and R3 is CH₃, and the other is H. Further, at least one of R4 and R6 is F and the other is H.

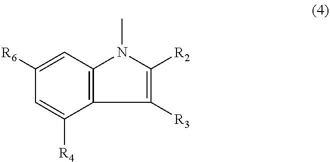

When these substances are used as a host material, they are preferably used as polyvinyl indole in which indole skeletons are bonded to the main chain in a pendent form.

Presently, the most studied blue emitting dopant FIrpic has a luminescent wavelength and absorption wavelength at about 475 nm and 380 nm, respectively. In view of the color rendering property, practical application of an emitting dopant of deeper blue color has been desired, which has a shorter luminescent wavelength than that of FIrpic. Deep blue emitting dopants which have been reported include, for example, bis(4,6-difluorophenylpyridinato)tetrakis(1-pyrazolyl)borateiridium (III) [FIr6: luminescent wavelength 457 nm], tris(1-phenylpyrazorato-N, C2′)iridium (III) [Ir(ppz)₃: luminescent wavelength 414 nm], and tris(1-phenyl-3-methylimidazoline-2-iriden-C, C2′)iridium (III) [Ir(pmi)₃: luminescent wavelength 383 nm]. The structures of these emitting dopants are indicated below.

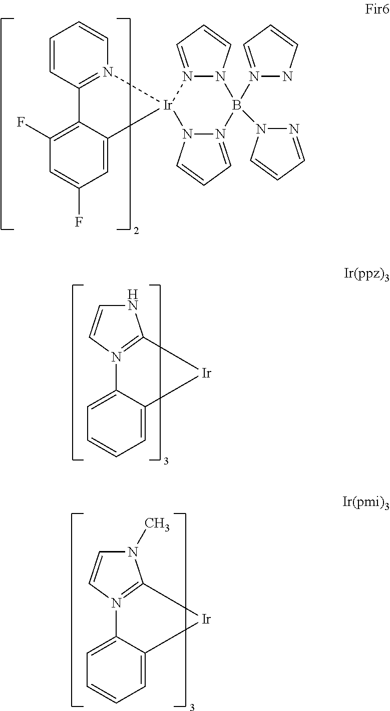

In the present embodiment, the deep blue emitting dopants can emit light efficiently by applying the aforementioned host materials whose luminescent wavelength is shifted toward a shorter wavelength, to an emissive layer.

The desired property of a host material in the emissive layer utilizing phosphorescence is to prevent an emitting dopant from inactivation of exciton triplet state. In order to exhibit this desired property, the exciton triplet energy of the host material is preferably higher than that of the emitting dopant. Therefore, the host material preferably has a shorter luminescent wavelength.

The host material containing indole skeletons has a hole transport property. In the case where the emissive layer consists of the host material having a high hole transport property and the emitting dopant only, the luminescent efficiency is decreased since holes in the emissive layer cannot be balanced with electrons therein. However, when indoles containing fluorine atoms represented by the general formulae (3) and (4) are used, the aforementioned problem of luminescent efficiency is difficult to be caused, since introducing fluorine atoms enhances electron supply relatively owing to the improvement of electron affinity of the host material. Further, according to molecular orbital calculation, the luminescent wavelength is estimated to be shifted toward a shorter wavelength by introducing fluorinate atoms at 4- or 6-position of indole (Tetrahedron Letters, 45, pp. 4899-4902 (2004)). Therefore, a host material having a molecular skeleton containing a fluorine atom at 4- or 6-position is able to enhance electron supply without shift of the luminescent wavelength to longer wavelength.

Alternatively, an emissive layer may further contain an electron transport material for balancing holes and electrons in the emissive layer. As the electron transport material, for example, 2-(4-biphenylyl)-5-(p-t-butylphenyl)-1,3,4-oxadiazol [hereinafter, referred to as tBu-PBD] and 1,3-bis(2-(4-t-butylphenyl)-1,3,4-oxydiazol-5-yl)benzene [hereinafter, referred to as OXD-7] can be used.

A method for forming the emissive layer 14 includes, for example, spin coating, but is not particularly limited thereto as long as it is a method which can form a thin film. A solution containing an emitting dopant, host material, and electron transport material is applied in a desired thickness, followed by heating and drying with a hot plate and the like. The solution to be applied may be filtrated with a filter in advance.

The thickness of the emissive layer 14 is preferably 10-100 nm. The ratio of the host material, emitting dopant, and electron transport material in the emissive layer 14 is arbitrary as long as the effect of the present invention is not impaired. However, the amounts of the host material, emitting dopant, and electron transport material are preferably 30-98% by weight, 2-15% by weight, and 0-68% by weight, respectively.

The substrate 11 is a member for supporting other members. The substrate 11 is preferably one which is not modified by heat or organic solvents. A material of the substrate 11 includes, for example, an inorganic material such as alkali-free glass and quartz glass; plastic such as polyethylene, PET, PEN, polyimide, polyamide, polyamide-imide, liquid crystal polymer, and cycloolefin polymer; polymer film; and metal substrate such as SUS and silicon. In order to obtain light emission, a transparent substrate consisting of glass, synthesized resin, and the like is preferably used. Shape, structure, size, and the like of the substrate 11 are not particularly limited, and can be appropriately selected in accordance with application, purpose, and the like. The thickness of the substrate 11 is not particularly limited as long as it has sufficient strength for supporting other members.

The anode 12 is laminated on the substrate 11. The anode 12 injects holes into the hole injection/transport layer 13 or the emissive layer 14. A material of the anode is not particularly limited as long as it exhibits conductivity. Generally, a transparent or semitransparent material having conductivity is deposited by vacuum evaporation, sputtering, ion plating, plating, and coating methods, and the like. For example, a metal oxide film and semitransparent metallic thin film exhibiting conductivity may be used as the anode 12. Specifically, a film prepared by using conductive glass consisting of indium oxide, zinc oxide, tin oxide, indium tin oxide (ITO) which is a complex thereof, FTO, indium zinc oxide, and the like (NESA etc.); gold; platinum; silver; copper; and the like are used. In particular, it is preferably a transparent electrode consisting of ITO. As an electrode material, organic conductive polymer polyaniline, the derivatives thereof, polythiophene, the derivatives thereof, and the like may be used. When ITO is used as the anode 12, the thickness thereof is preferably 30-300 nm. If the thickness is thinner than 30 nm, the conductivity is decreased and the resistance is increased, resulting in reducing the luminescent efficiency. If it is thicker than 300 nm, ITO loses flexibility and is cracked when it is under stress. The anode 12 may be a single layer or laminated layers each composed of materials having various work functions.

The hole injection/transport layer 13 is optionally arranged between the anode 12 and emissive layer 14. The hole injection/transport layer 13 receives holes from the anode 12 and transports them to the emissive layer side. As a material of the hole injection/transport layer 13, for example, polythiophene type polymer such as a conductive ink, poly(ethylenedioxythiophene):polystyrene sulfonate [hereinafter, referred to as PEDOT:PSS] can be used, but is not limited thereto. A method for depositing the hole injection/transport layer 13 is not particularly limited as long as it is a method which can form a thin film, and may be, for example, a spin coating method. After applying a solution of hole injection/transport layer 13 in a desired film thickness, it is heated and dried with a hotplate and the like. The solution to be applied may be filtrated with a filter in advance.

The electron injection/transport layer 15 is optionally arranged between the emissive layer 14 and cathode 16. The electron injection/transport layer 15 receives electrons from the cathode 16 and transports them to the emissive layer side. As a material of the electron injection/transport layer 15 is, for example, CsF, tris(8-hydroxyquinolinato)aluminum [hereinafter, referred to as Alq₃], and LiF, but is not limited thereto. A method for depositing the electron injection/transport layer 15 is similar to that for the hole transport layer 13.

The cathode 16 is laminated on the emissive layer (or the electron injection/transport layer 15). The cathode 16 injects electrons into the emissive layer 14 (or the electron injection/transport layer 15). Generally, a transparent or semitransparent material having conductivity is deposited by vacuum evaporation, sputtering, ion plating, plating, coating methods, and the like. Materials for the cathode include a metal oxide film and semitransparent metallic thin film exhibiting conductivity. When the anode 12 is formed with use of a material having high work function, a material having low work function is preferably used as the cathode 16. A material having low work function includes, for example, alkali metal and alkali earth metal. Specifically, it is Li, In, Al, Ca, Mg, Li, Na, K, Yb, Cs, and the like.

The cathode 16 may be a single layer or laminated layers each composed of materials having various work functions. Further, it may be an alloy of two or more metals. Examples of the include a lithium-aluminum alloy, lithium-magnesium alloy, lithium-indium alloy, magnesium-silver alloy, magnesium-indium alloy, magnesium-aluminum alloy, indium-silver alloy, and calcium-aluminum alloy.

The thickness of the cathode 16 is preferably 10-100 nm. When the thickness is thinner than the aforementioned range, the resistance is excessively high. When the film thickness is thicker, long period of time is required for deposition of the cathode 16, resulting in deterioration of the performance due to damage to the adjacent layers.

Explained above is an organic light-emitting diode in which an anode is laminated on a substrate and a cathode is arranged on the opposite side to the substrate, but the substrate may be arranged on the cathode side.

### EXAMPLES

### Example 1

As example 1, an organic light-emitting diode utilizing polyvinyl indole as a host material was prepared.

On a glass substrate, a transparent electrode having a thickness of 50 nm and consisting of ITO (indium tin oxide) was formed by vacuum evaporation. As a material of a hole transport layer, an aqueous solution of PEDOT:PSS was used. The aqueous solution was applied to the anode by spin coating, followed by heating and drying to provide a hole injection/transport layer having a thickness of 55 nm.

As for an emissive layer, polyvinyl indole, OXD-7, and FIr6 were used as a host material, electron transport material, and a blue emitting dopant, respectively. These substances were weighed in a weight ratio of polyvinyl indole: OXD-7:FIr6=65:30:5, and dissolved in chlorobenzene. The solution was applied to the hole injection/transport layer by spin coating, heated at 100° C. for 10 minutes, and dried, thereby forming an emissive layer having a thickness of 75 nm.

An electron injection/transport layer having a thickness of 1 nm was formed on the emissive layer by vacuum evaporation of CsF. A cathode having a thickness of 150 nm was formed on the electron injection/transport layer.

(Test 1)

Luminescent spectra of polyvinyl indole and polyvinyl (4,6-difluoroindole) were compared to each other. In the comparison, a thin film was formed by each of the aforementioned materials, and the luminescent intensity was measured for each film. The thin film was obtained by applying the aforementioned chlorobenzen solution of each host material (5% by weight) to the washed glass substrate by spin coating, followed by heating and drying at 100° C. for 10 minutes.

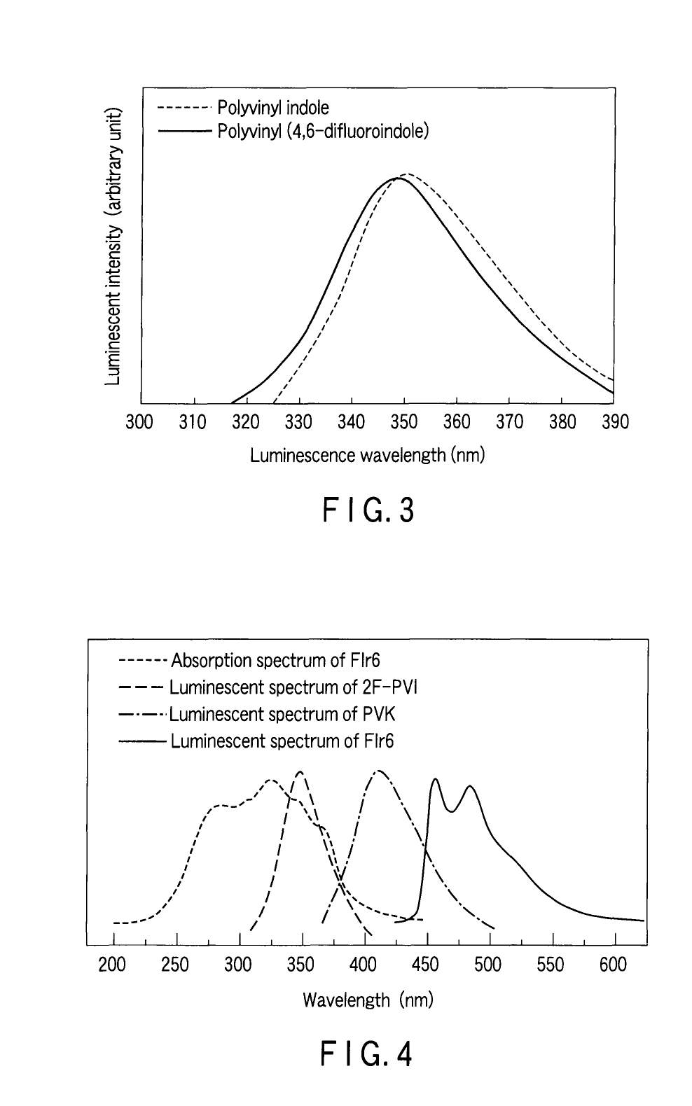

FIG. 3 shows luminescence spectra of polyvinyl indole [PVI] and polyvinyl (4,6-difluoroindole)[2F-PVI]. As for polyvinyl (4,6-difluoroindole) in which fluorine atoms are introduced into 4- and 6-positions, the luminescent wavelength was shifted toward shorter wavelength than that of polyvinyl indole. The luminescent wavelength was confirmed to shift toward a shorter wavelength by introducing fluorine atoms.

Luminescent wavelength was measured for each of other derivatives. The results are shown in Table 1 below.

TABLE 1

| | Luminescent |
|---|---|
| Host | wavelength |
| material | (nm) |
| 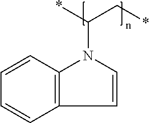 | 350 |
| 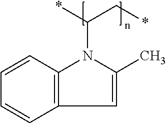 | 356 |
| 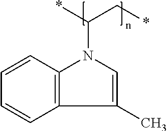 | 360 |
| 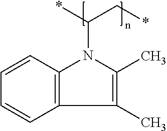 | 366 |
| 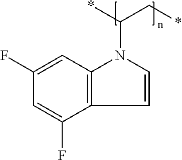 | 348 |
| 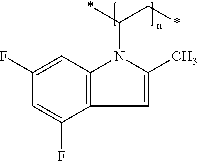 | 354 |
| 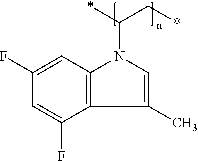 | 356 |
| 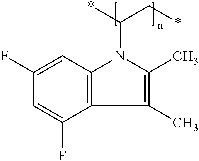 | 363 |

The results show that all derivatives indicate luminescent wavelengths shifted toward shorter wavelengths in comparison to conventional polyvinyl carbazole. Further, it was confirmed that introducing fluorine atoms caused shift of a luminescence wavelength toward a shorter wavelength. By using the derivatives as a host material, efficient energy transfer to an emitting dopant having deeper blue color is achieved. With use of any one of the derivatives, an organic light-emitting diode can be prepared as is the case with the aforementioned example 1.

(Test 2)

Luminescent spectra of polyvinyl (4,6-difluoroindole) and polyvinyl carbazole were measured, and compared with an absorption spectrum and a luminescent spectrum of FIr6. FIr6 is a dopant having an absorption band in a shorter wavelength range than FIrpic and exhibiting a deep blue color.

FIG. 4 compares overlap between luminescent spectra of a host material and absorption spectra of emitting dopants. The energy transfer based on Foerster's mechanism is proportional to the overlapped area between the luminescence spectra of a host material and the absorption spectra of an emitting dopant. More specifically, as the overlapped area is larger, the energy transfer becomes more efficient and luminescence efficiency is increased. In comparison between the luminescent spectra, overlapped area of polyvinyl (4,6-difluoroindole) with absorption spectrum of FIr6 is about three times as large as that of polyvinyl carbazole. Therefore, polyvinyl (4,6-difluoroindole) achieves light emission from a deeper blue color emitting dopant more efficiently when it is used as a host material.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An organic light-emitting diode comprising:
an anode and a cathode arranged apart from each other; and
an emissive layer arranged between the anode and the cathode and containing a host material and an emitting dopant, the host material containing a plurality of indole skeletons represented by the general formula (1):

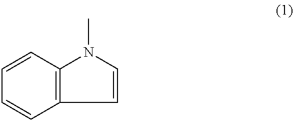

2. The organic light-emitting diode according to claim 1, wherein the host material contains a plurality of indole skeletons having one or more methyl groups at 2- or 3-position represented by the general formula (2): 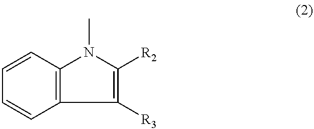
where at least one of R2 and R3 is CH₃ and the other is H.

3. The organic light-emitting diode according to claim 1, wherein the host material contains a plurality of indole skeletons having one or more fluorine atoms at 4- or 6-position represented by the general formula (3): 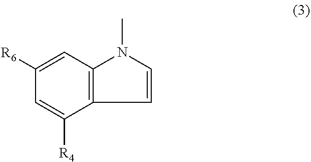
where at least one of R4 and R6 is F and the other is H.

4. The organic light-emitting diode according to claim 1, wherein the host material contains a plurality of indole skeletons having one or more methyl groups at 2- or 3-position and one or more fluorine atoms at 4- or 6-position represented by the general formula (4): 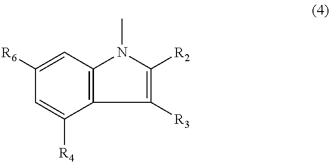
where at least one of R2 and R3 is CH₃ and the other is H, and at least one of R4 and R6 is F and the other is H.
